(19) United States
(12) Patent Application Publication
(10) Pub. No.: US 2006/0081459 A1
(43) Pub. Date: Apr. 20, 2006

(54) In-situ monitoring of target erosion

(75) Inventors: Kenneth Chien-Quen Tsai, Emerald Hills, CA (US); Kenny King-Tai Ngan, Fremont, CA (US)

Correspondence Address: APPLIED MATERIALS, INC.;Patent Department, M/S 2061, P.O. Box 450A, Santa Clara, CA, 95052, US

(73) Assignee: Applied Materials, Inc.

(21) Appl. No.: 10/968,367

(22) Filed: Oct. 18, 2004

(51) Int. Cl. C23C 14/00

(52) U.S. Cl. 204/192.13; 204/298.02; 204/298.03

(57) ABSTRACT

A target sputtering apparatus capable of monitoring target erosion has a sputtering chamber having a sputtering target with a sputtering surface. The apparatus can have a wireless receiver to receive a wireless signal and a controller to control the receiver and components of the sputtering chamber to sputter-deposit material on a substrate, and monitor erosion of the sputtering surface of the sputtering target. The controller also has a target erosion monitoring code that includes detection wafer transport program code to transport a detection wafer onto the support in the chamber, wherein the detection wafer generates a wireless signal in relation to an extent of erosion of the sputtered surface, and erosion determination code to analyze the wireless signal received by the wireless receiver and originating from the detection wafer to determine an extent of erosion of the sputtering surface of the sputtering target.

### BACKGROUND

The present invention relates to the in-situ monitoring of sputtering targets used in substrate sputtering processes.

A sputtering chamber is used to sputter deposit material onto a substrate, such as for example integrated circuit chips and displays, to manufacture electronic circuits. Typically, the sputtering chamber comprises an enclosure wall that encloses a process zone into which a process gas is introduced, a gas energizer to energize the process gas, and an exhaust port to exhaust and control the pressure of the process gas in the chamber. The chamber is used to sputter deposit a material from a sputtering target onto the substrate. The sputtered material may be a metal, such as for example aluminum, copper, tungsten, titanium, cobalt, nickel or tantalum. The sputtered material may also be a metal compound, such as for example tantalum nitride, tungsten nitride or titanium nitride. In the sputtering processes, the sputtering target is bombarded by energetic ions formed in the energized gas, causing material to be knocked off the target and deposited as a film on the substrate. The sputtering chamber can also have a magnetic field generator that shapes and confines a magnetic field about the target to improve sputtering of the target material.

In these sputtering processes, certain regions of the target are often sputtered at higher sputtering rates than other regions resulting in uneven sputtering of the target surface. For example, uneven target sputtering can arise from the contoured magnetic field maintained about the target to confine or stir energized gas ions about the target surface. Uneven sputtering can also be related to differences in grain size or structure of the target material, chamber shape and geometry, and other factors. Uneven target sputtering can result in sputtered depressions in the target, such as for example, pits, grooves, race-track like trenches, and other recesses, where material has been sputtered from the target at a higher rate than the surrounding areas. The formation of such depressions is undesirable because they can result in the deposition of a sputtered film having varying thickness on the substrate. Deep depressions and grooves in the target can also expose chamber components, such as backing plates, behind the target. Sputtering of material from the backing plate can contaminate substrates being processed in the chamber.

Accordingly, sputtered targets are typically used and removed from the chamber after the processing of a predefined number of substrates, before the depressions and grooves formed on the target become too deep, wide or numerous, and the targets can be either refurbished or disposed of. The sputtering target erosion endpoint, corresponding to the number of substrates that can be processed before removal of the sputtering target from the chamber is required, is typically estimated by evaluating the target after substrate processing. For example, after processing one or more substrates in a sputtering process, the process chamber can be opened to atmospheric pressure, and the target removed from the chamber, to allow visual inspection of the sputtering target. If the sputtering target has very wide or deep depressions or grooves, then processing with the target is stopped. If the target is not excessively eroded, the target is placed back in the chamber, a vacuum pressure in the chamber is re-established, and processing is continued with a subsequent batch of substrates until the inspection process is repeated. By recording the total number of substrates that can be processed before the target is excessively eroded, an estimate of the target erosion endpoint can be determined for a particular sputtering process.

However, this method of determining the sputtering target erosion endpoint can be inefficient and undesirably costly. Determining a very accurate target erosion endpoint estimate can require processing multiple batches of test substrates, and carefully inspecting the target for the extent of erosion, which can take an undesirably long time. The target erosion endpoint determined by the estimation means can also be undesirably inaccurate, as the rate and nature of the erosion of the target may vary from substrate to substrate, and the erosion may be entirely different from the estimate if the sputtering process parameters are varied. Accordingly, in some instances, the sputtering target may be removed from the chamber only after excessive erosion has occurred, which can contaminate the substrates being processed in the chamber and/or result in poorly processed substrates. The target may also be accidentally removed from the chamber too soon when relying on such an erosion endpoint estimate, leading to a time-consuming and unnecessary shut-down of the chamber, and a waste of un-used target material. Furthermore, the erosion endpoint estimate may not be a good predictor of the erosion endpoint for processes having different sets of processing parameters, and thus may have to be painstakingly re-estimated for every new process performed in a chamber. Thus, this method of estimating the sputtering target erosion endpoint typically does not provide satisfactory results.

Thus, it is desirable to have a method of determining when erosion of a sputtering target has occurred. It is furthermore desirable to have a method of sputter processing substrates without excessively eroding the sputtering target.

### SUMMARY

In one version, a target sputtering apparatus capable of monitoring target erosion has a sputtering chamber having a sputtering target with a sputtering surface, a substrate support facing the sputtering target, a transport, a sputtering gas supply, a gas energizer, and a gas exhaust. A sputtering gas can be maintained at a pressure in the chamber and energized to sputter material from the sputtering surface of the sputtering target. The apparatus also has a wireless receiver to receive a wireless signal, and a controller to control the support, transport, sputtering target, gas supply, gas energizer, gas exhaust and receiver. The controller has (i) process control program code to sputter-deposit material on a substrate, and (ii) target erosion monitoring code to monitor erosion of the sputtering surface of the sputtering target. The target erosion monitoring code includes detection wafer transport program code to transport a detection wafer onto the support in the chamber, wherein the detection wafer generates a wireless signal in relation to an extent of erosion of the sputtered surface, and erosion determination code to analyze the wireless signal received by the. wireless receiver and originating from the detection wafer to determine an extent of erosion of the sputtering surface of the sputtering target.

In one version, a method of monitoring the sputtering target in the process chamber includes sputtering the target in the process chamber to form a sputtered surface on the target. A detection wafer is provided on a support facing the target, the detection wafer having a plurality of sensors that detect an extent of erosion of the sputtered surface, and generate a signal in relation to the extent of erosion. The signal is wirelessly transmitted to a receiver, and the signal is analyzed to determine the extent of erosion of the sputtered surface.

In another version, a method of measuring a surface profile of an asymmetrically sputtered region of a sputtering target in a process chamber is provided. In the method, a detection wafer is provided in the chamber. The detection wafer has a plurality of sensors to measure the surface profile of substantially the entire asymmetrically sputtered region of the sputtering target, in-situ in the chamber, and without movement of the detection wafer during the measurement. A signal is generated in relation to the measured surface profile, and the signal is analyzed to determine the surface profile of the asymmetrically sputtered region of the sputtering target.

In one version, a wafer to monitor a sputtering target in a process chamber has a disc to be held by a support in a process chamber, and a plurality of sensors on a top surface of the disc. The sensors include a radiation source to direct radiation onto a surface of the sputtering target, and a detector to detect radiation reflected by the surface and generate a signal in relation to the detected radiation. The wafer also has a wireless transmitter to receive the signal from the detector, and wirelessly transmit the signal to a receiver that is outside of the process chamber.

In yet another version, the wafer is capable of measuring a surface profile of an asymmetrically sputtered region of a sputtering surface on a sputtering target in a process chamber. In this version, the wafer has a plurality of sensors spaced apart and arranged on the top surface to measure, in-situ in the chamber, a surface profile of substantially the entire asymmetrically sputtered region of the sputtering target. The sensors have a radiation source to direct radiation onto the sputtering surface of the sputtering target and a detector to detect radiation reflected by the sputtering surface and generate a signal in relation to the detected radiation.

In another version, the sputtering apparatus has a sensor mounted on a sidewall of the chamber that directs radiation at the sputtering surface of the target, detects radiation reflected from the sputtering surface, and generates a signal in relation to the detected radiation. The controller controls the sensor and components of the chamber to sputter-deposit material on a substrate in the chamber, and has target erosion monitoring code to analyze the signal generated by the sensor to determine an extent of erosion of the sputtering surface of the sputtering target. A method of monitoring a sputtering target in the process chamber includes directing radiation towards the sputtered surface of the target from a sidewall of the process chamber, receiving radiation reflected towards the sidewall from the sputtered target, and generating a signal in relation to the received radiation to determine an extent of erosion of the sputtered surface region.

In yet another version, the sputtering apparatus has an eddy current sensor mounted on a back side of the sputtering target. The eddy current sensor detects an eddy current in the sputtering target and generates a signal in relation to the detected eddy current. The controller controls the eddy current sensor and components of the process chamber to sputter-deposit material on a substrate, and has target erosion monitoring code to analyze the signal generated by the eddy current sensor to determine an extent of erosion of the sputtered surface. A method of monitoring the sputtering target in the process chamber includes mounting an eddy current sensor on a back side of the sputtering target, sputtering a front side of the sputtering target in the process chamber to form a sputtered surface on the target, and detecting an eddy current in the sputtering target, and generating a signal in relation to the eddy current to determine an extent of erosion of the target.

In yet another version, the sputtering apparatus has a sheet resistance monitor mounted on a back side of the sputtering target that detects a sheet resistance of the target and generates a signal in relation to the detected sheet resistance. The controller has target erosion monitoring code to analyze the signal generated by the sheet resistance sensor to determine an extent of erosion of the sputtered surface. A method of monitoring the sputtering target in the process chamber includes mounting the sheet resistance sensor on a back side of the sputtering target, sputtering a front side of the sputtering target in the process chamber to form a sputtered surface on the target, and detecting a sheet resistance in the sputtering target, and generating a signal in relation to the sheet resistance to determine an extent of erosion of the target.

### DRAWINGS

These features, aspects and advantages of the present invention will become better understood with regard to the following description, appended claims, and accompanying drawings, which illustrate examples of the invention. However, it is to be understood that each of the features can be used in the invention in general, not merely in the context of the particular drawings, and the invention includes any combination of these features, where:

FIG. 1 is a partial sectional side view of an embodiment of a sputtering target having a sputtering surface with eroded regions;

FIG. 2A is a partial sectional side view of an embodiment of a chamber with a detection wafer and wireless receiver;

FIG. 2B is a partial top view of an embodiment of a detection wafer having a plurality of sensors;

FIG. 3 is a partial sectional side view of an embodiment of a chamber having sidewall-mounted sensors;

FIG. 4 is a partial sectional side view of an embodiment of a chamber having a detector mounted on a backside of sputtering target;

FIG. 5 is a partial sectional side view of an embodiment of a process chamber suitable for sputter-depositing material on a substrate; and

FIG. 6 is an illustrative block diagram of an embodiment of a controller comprising a computer readable program.

### DESCRIPTION

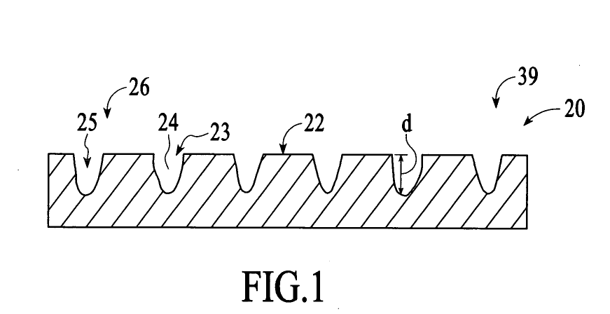

An embodiment of a target 20 capable of depositing material on a substrate 104 is shown in FIG. 1. The target material can comprise a metal, such as for example at least one of titanium, aluminum, tantalum, tungsten, and copper, and can also comprise metals such as at least one of germanium, selenium and tellurium. The target 20 may have a surface 22 from which material is removed to deposit the material on the substrate 104, as shown for example in FIG. 1. For example, the surface 22 can comprise a sputtering surface that is sputtered by energized gas ions to remove sputtering material from the surface 22. The surface 22 of the target can also be used to deposit material on a substrate by another method. For example, an electromagnetic energy beam, such as a laser or electron beam, can be directed onto the surface to break material away from the surface 22.

In one version, the surface 22 comprises one or more eroded regions 23 that form as a result of removing material from the surface, for example by sputtering of material from that region 23 of the surface 22. In one version, the surface 22 comprises a sputtered depression 24 that is formed in the surface 22 as the result of, for example, uneven sputtering rates across the surface 22. For example, the sputtered depressions 24 can be grooves having multiple concentric rings 25, centered about the middle of the target 20. The target 20 can comprise from about 1 to about 6 of the rings 25, and the rings 25 can comprise depths in the target 20 of up to about 5 cm, such as about 3.5 cm, and can also comprise a width at the top of the ring of up to about 7.5 cm. The sputtered depressions 24 can also take other shapes and forms, such as pits, channels, holes or dish shaped depressions. The shape of the depressions 24 is dependent upon the target material, the shape and symmetry of the energy field applied to sputter or otherwise remove material from the target, and even the shape of any magnetic field applied across or from behind the target. Thus, the scope of the invention should not be limited to particular targets 20 or shapes of the depressions 24 formed in the targets 20.

In one version, the extent of erosion of the target 20 can be detected by a target erosion detection method. The target erosion detection method is desirably capable of detecting erosion of the target 20 while the target 20 remains in the process chamber 106, without requiring removal of the target 20 from the chamber. The target erosion method is also desirably capable of detecting erosion while maintaining a vacuum in the process chamber 106, and without venting the chamber 106 to atmospheric pressure. The erosion method may be capable of detecting erosion of the surface 22 of the target, for example by detecting eroded regions 23 of the target, and may even be capable of determining a sputtered surface profile of the target surface 22. The surface profile of the sputtering surface 22 may comprise the depths of eroded regions 23 in the surface 22, or the remaining thickness of the target 20, at a plurality of different points across the surface 22. The extent of erosion may also be detected to determine when an erosion endpoint has occurred, the erosion endpoint being the point at which the target has been sputtered to a predetermined maximum state, such as a sputtered state immediately before break-through to a backing plate occurs. The extent of erosion of the target can be monitored by providing a target erosion monitoring system 42 as a part of the sputtering apparatus 102.

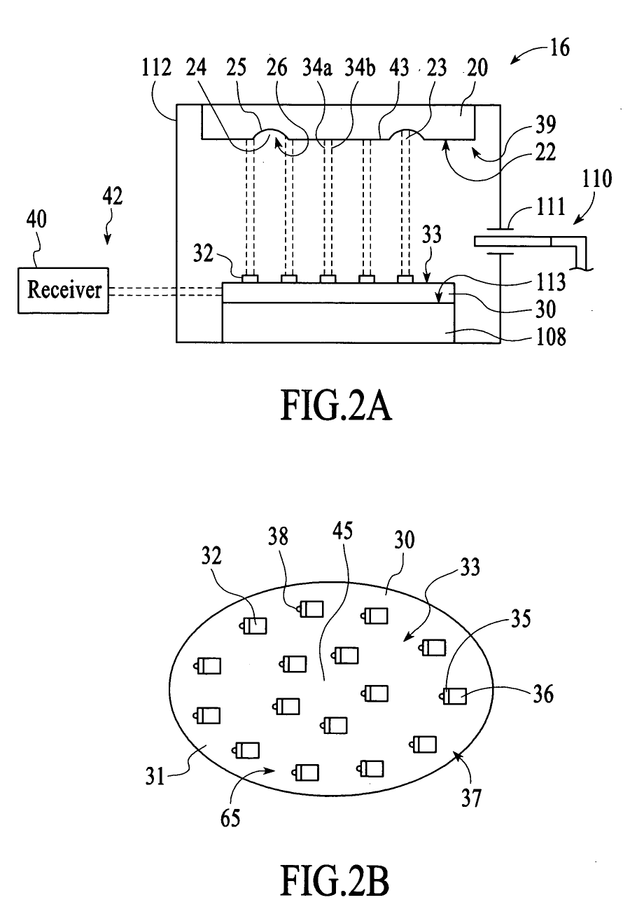

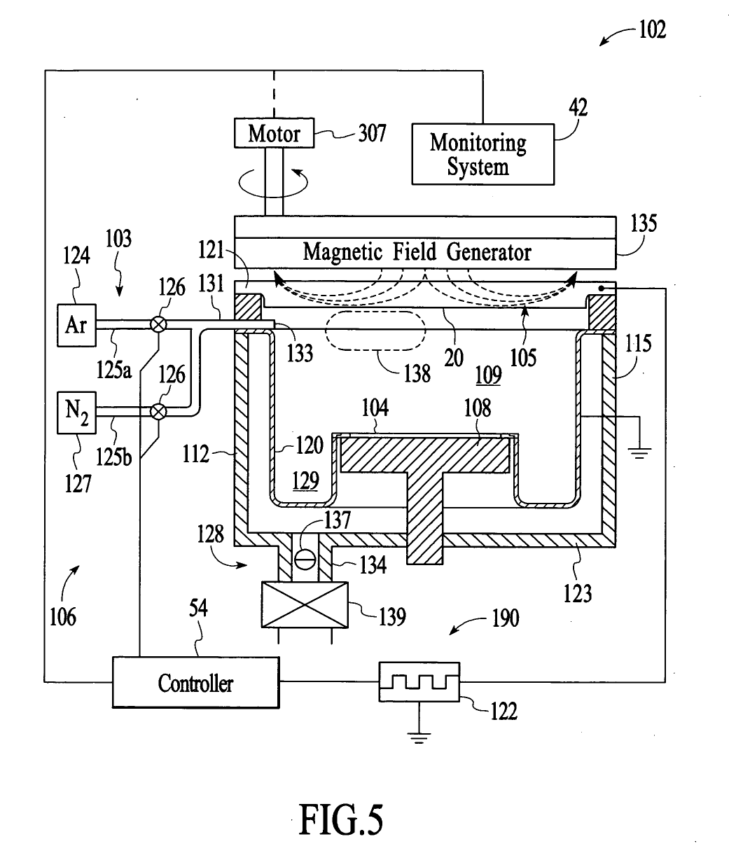

In one version, the target 20 can be monitored to determine an erosion extent by providing a target erosion monitoring system 42 comprising a detection wafer 30 that is capable of detecting erosion of the target surface 22, as shown for example in FIG. 2a. The detection wafer 30 comprises a disc 31 that is shaped and sized to be held on a surface 113 of a support 108 that is used to support substrates 104 during processing in the chamber 106, and is positioned facing the sputtering surface 22 of the target 20, as shown for example in FIG. 5. The detection wafer 30 can be loaded into the chamber 106 via a loading inlet 111 in a wall of the chamber 106, using a transport assembly 110. The transport assembly 110 is desirably capable of transporting the wafer 30 while a vacuum pressure is maintained in the chamber 106, and may also be the assembly used to transport substrates 104 into the chamber 106. The detection wafer 30 can be provided in the chamber 106 after processing one or a plurality of substrates 104, such as for example after processing at least about 500 substrates 104, and less than about 30,000 substrates 104, and can be used to periodically monitor the target sputtering surface 22.

The detection wafer 30 comprises at least one and even a plurality of sensors 32 to detect target erosion in-situ in the process chamber 106, as shown for example in FIGS. 2a and 2b. For example, the sensors 32 may be capable of measuring a distance to the target surface 22 to determine an extent of erosion of the surface 22, with a larger distance indicating a deeper depression 24 and greater extent of erosion. The sensors 32 can be distributed across a top surface 33 of the detection wafer 30 that faces the sputtering target 20, to allow monitoring at different points across the surface 22 of the target 20. In one version, the sensors 32 are positioned on the detection wafer 30 to monitor regions 23 of the target 20 that are known to be susceptible to erosion. For example, the sensors 32 can be positioned such that they lay beneath regions 23 where sputtered depressions 24 typically form when placed on the support 108 in the chamber 106. In another version, the sensors 32 can be positioned to obtain a surface profile measurement of the surface 22. For example, a plurality of sensors 32 can be provided on the detection wafer surface 33 to monitor both regions of the target 20 that typically become eroded, as well as regions that do not typically become eroded, and obtain an overall profile of the surface 22.

In one version, the detection wafer 30 comprises sensors 32 that are spaced apart and arranged to measure a surface profile of an asymmetrically sputtered region 26 of the sputtering surface 22 of the target 20. For example, the sensors 32 may be spaced apart and arranged on the top surface 33 of the detection wafer 30 to determined a surface profile of a sputtered depression 24 that forms a ring 25, such as an annular track 25, in the surface 22 of the sputtering target 20. In one version, the sensors 32 are spaced apart and arranged in an annular shape 37 on the detection wafer 30, to improve measurement of an asymmetrically sputtered region 26 comprising an annular track 25 on the sputtering surface 22. For example, for an annular track 25 that is located at a periphery 39 of the target 20, the sensors 32 may be spaced apart and arranged in an annular shape 37 about a peripheral region 65 of the detection wafer 30. As another example, for an annular track 25 that is located about midway along the radius of the target 20, such as between the periphery 39 of the target 20 and the center 43 of the target 20, the sensors 32 may be spaced apart and arranged in an annular shape 37 located between the peripheral region 65 and a center region 45 of the detection wafer 30. The sensors 32 may also be spaced apart and arranged in a plurality of annular shapes 37, such as along concentric circles, to allow measurement of annular tracks 25 having different radii in the sputtering surface 22. Alternatively, the sensors 32 can be spaced apart and arranged in other configurations suitable to determine an extent of erosion and/or surface profile of the sputtering surface 22.

The sensors 32 desirably allow an extent of erosion of a portion of the sputtering surface 32 to be measured substantially without requiring movement of the detection wafer 30 during the measurement. For example, the surface profile of substantially the entire asymmetrically sputtered region 26 of the sputtering surface 22 may be measured substantially without moving the detection wafer 30 about in the chamber. Allowing the sputtering surface measurement to be made without moving the detection wafer 30 reduces the error in the measurement due to vibration or movement of measurement components, and simplifies the overall measurement process.

In one version, the detection wafer 30 comprises sensors 32 adapted to detect a property of radiation reflected from the target surface 22. For example, a sensor 32 on the detection wafer 30 can comprise a radiation source 35 adapted to generate a beam of incident radiation 34a that is directed towards the target surface 22, as shown for example in FIG. 2a. The sensor 32 further comprises a detector 36 that is capable of detecting a property of a beam of reflected radiation 34b from the target surface 22, such as one or more of an intensity and phase of the reflected radiation beam, and generating a signal in relation to the detected radiation. Detection of the reflected radiation beam can be used, for example, to estimate the distance from the wafer 30 to the surface 22 of the target 20, and thus estimate the depth of eroded regions 23 in the target 20. For example, a time delay between the emission of the incident radiation beam 34a and detection of the reflected radiation beam 34b can be measured to determine the separation distance between the target surface 22 and detection wafer 30. As another example, a change in phase of the reflected radiation beam 34b can be detected to determine a distance to the target surface 22. Also, properties of a pulsed radiation beam can be detected. In another version, an interferometric method can be used to determine at least one of a distance to the target surface 22 and a remaining thickness of the target 20.

The radiation source 35 is desirably capable of generating radiation having properties that are suitable for detecting an extent of erosion of the target surface 22. For example, a suitable radiation source 35 may comprise at least one of a laser diode, ultrasonic transducer, sound wave generator and electron beam generator. The detector 36 is capable of detecting one or more properties of the reflected radiation, and can comprise, for example, at least one of a photodiode, charge coupled device (CCD) and ultrasonic receiver. Other examples of suitable sensors 32 can include capacitive sensors and inductive sensors. In one version, the detection wafer 30 comprises a plurality of sensors 32 each having a radiation source 35 and detector 36, as shown for example in FIG. 2b. The sensors 32 may also comprise a plurality of detectors 36 for each radiation source 35, or a plurality of sources 35 for each detector 36 (not shown), according to the target measurements and sensor configurations that are desired.

The detector 36 generates a signal in relation to the detected property of radiation, and the signal can be analyzed to determine an extent of erosion of the target sputtering surface 22. For example, the signal can be at least one of an electrical signal and an optical signal. In one version, the signal is generated by the wireless transmitter 38 that is capable of wirelessly transmitting the signal to a wireless receiver 40 that is remote from the detection wafer 30. By “wireless” it is meant that the signal is transmitted using electromagnetic waves, such as RF, infrared, laser, visible light, and acoustic energy, without the use of wire conductors connecting the transmitter 38 and receiver 40, as in the transmission of an RF signal using a wireless protocol, and other wireless methods known to those of ordinary skill in the art. The detection wafer 30 can comprise one or a plurality of wireless transmitters 38 that are capable of receiving signals from one or more detectors 36. For example, each sensor 32 can comprise a wireless transmitter 38 (as shown), or the detection wafer 30 may comprise a single transmitter that transmits signals from multiple sensors and 32/or detectors 36.

The wireless receiver 40 is located at a region that is remote from the detection wafer 30, such as outside the chamber enclosure walls 112, such that the signal from the detection wafer 30 can be received outside of the chamber for processing and/or analysis. Alternatively, the wireless receiver 40 can be at least partially embedded in an enclosure wall 40, but is desirably external to the process zone 109 of the process chamber 106. The wireless receiver 40 may be capable of providing the wireless signal to a chamber controller 300 that comprises program code to control processing of substrates 104 and monitoring of the extent of erosion of the target 20. The controller 300 and receiver 40 may be housed in the same or different enclosures, according to the desired configuration and operation. The wireless transmission of the detection signal to the receiver 40 is advantageous because the signal can be transmitted without requiring complex and cumbersome wiring to connect the detection wafer 30 to the receiver 40. The wireless transmission also allows for the receiver 40 to be placed outside of the chamber 106, so that the receiver 40 does not have to be exposed to potentially erosive sputtering gas. Thus, the detection wafer 30 comprising the wireless transmitter 38 allows for the target 20 to be monitored while in the chamber and while the chamber is maintained under vacuum pressure, substantially without exposing sensitive detection devices to erosive sputtering gases during the processing of substrates 104.

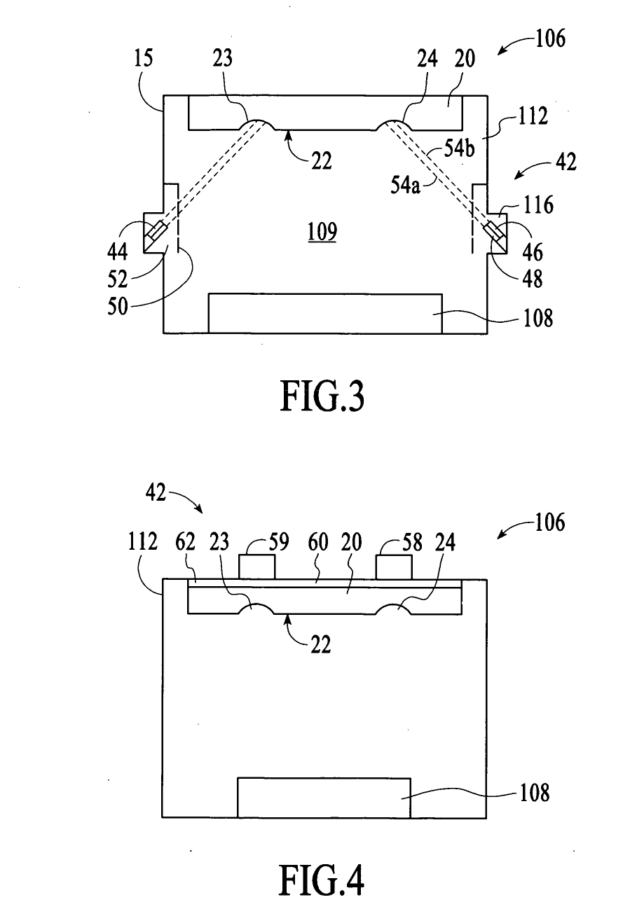

In yet another version, the extent of erosion of the target sputtering surface 22 is detected by providing a target erosion monitoring system 42 comprising at least one sensor 44 that is mounted on a sidewall 115 of the chamber 106, as shown for example in FIG. 3. The sensor 44 comprises a radiation source 46 adapted to direct radiation at the sputtering surface 22 of the target 20 from the chamber sidewall 115. The sensor 44 also comprises a detector 48 adapted to receive radiation that is reflected back from the target surface 22 and towards the sensor 44 mounted on the sidewall 115. The detector 48 generates a signal in relation to the detected radiation that can be analyzed to determine an extent of erosion of the sputtering surface 22. In one version, the sensor comprises a source 46 and detector 48 mounted on the same side of the sidewall 115 (as shown.) In another version, the source 46 and detector 48 can be mounted on opposing sides of the sidewall 115 (not shown). The sensor 44 is capable of monitoring the sputtering surface to determine an extent of erosion of the target surface 22, for example to determine at least one of a target erosion profile or target sputtering endpoint.

In one version, the sensor 44 is mounted in a recess 116 in the chamber sidewall 115, that extends outwardly and away from a sputtering process zone 109 in the chamber 106. The recess 116 inhibits the deposition of process residues onto the sensor 44 during processing of substrates 104 in sputter deposition processes, to enable proper function of the sensor 44. A shutter 50 can also be provided that fits over an opening 52 of the recess 116 during substrate processing to inhibit access of sputtering gas species and process deposits to the recess 116. The shutter 50 is opened when the sensor 44 is used to monitor the target sputtering surface 22, for example a chamber controller 300 can control opening of the shutter 50. Thus, mounting the sensor 44 on the chamber sidewall 115 is advantageous because the sensor 44 can be protected from erosion, while allowing clear and substantially unimpeded monitoring of the target surface 22 from inside the chamber 106. The sputtering surface 22 can be periodically monitored by the sensors 44, for example by monitoring after each substrate 104 is processed, and even after a batch of multiple substrates 104 have been processed in the chamber 106, such as from about 500 substrates 104 to about 30,000 substrates 104.

The sensor 44 comprises a radiation source 46 that is capable of generating an incident radiation beam 54a that is directed towards the target surface 22 and that has properties that are suitable for detecting an extent of erosion of the target surface 22. The sensor 44 further comprises a detector 48 that is capable of detecting a property of a reflected radiation beam 54b from the target surface 22, such as one or more of an intensity and phase of the reflected radiation beam, and generating a signal in relation to the detected radiation. In one version, the sensor 44 is capable of scanning an area of the sputtering surface 22, for example to determine a surface profile of the sputtering surface. For example, the sensor 44 may be adapted to rotate, or use other radiation directing, focusing or collimating elements to scan a radiation beam 54a across a surface region of the target 20, and even across substantially the entire sputtering surface 22 of the target 20. In yet another version, the sensors 44 may be positioned and adapted to direct radiation onto surface regions 23 that are especially susceptible to erosion, such as regions where eroded grooves 24 typically form.

Detection of the reflected radiation beam can be used, for example, to estimate the distance from the sensor 44 to regions on the surface 22 of the target 20, and thus estimate the depth of eroded regions 23 in the target 20. For example, similarly to the methods described for the detection wafer 30 above, a time delay between the emission of the incident radiation beam 54a and detection of the reflected radiation beam 54b can be measured to determine the separation distance between the target surface 22 and sensor 44. As another example, a change in phase of the reflected radiation beam 54b can be detected to determine a distance to the target surface 22. Also, properties of a pulsed radiation beam can be detected. In another version, an interferometric method can be used to determine at least one of a distance to the target surface 22 and a remaining thickness of the target 20. A suitable radiation source 46 may comprise, for example, at least one of a laser diode, ultrasonic transducer, sound wave generator and electron beam generator. Other examples of suitable sensors 44 can include capacitive sensors and inductive sensors. The detector 48 is capable of detecting one or more properties of the reflected radiation, and can comprise, for example, at least one of a photodiode, charge coupled device (CCD) and ultrasonic receiver.

In yet another version, the extent of erosion of the target sputtering surface 22 is detected by providing a target erosion monitoring system 42 that is capable of detecting an electromagnetic property of the target 20, such as for example at least one of an eddy current sensor 58 and a sheet resistance sensor 59, as shown for example in FIG. 4. The eddy current sensor 58 can be mounted on a back-side 60 of the target 20 that faces away from the substrate support 108, such as on top of the target backing plate 62, and thus is substantially not exposed to an energized gas environment. The eddy current sensor 58 is capable of inducing detectable eddy currents in the target material. For example, the eddy current sensor 58 may induce eddy currents in the target 20 by mutual induction with the target 20. In one version, the eddy current sensor 58 comprises one or more coils of wire through which an alternating current is passed. The alternating current in the coil generates a magnetic field that induces a current flow in the target material, which is typically referred to as and eddy current. The induced eddy currents produce magnetic fields that are detectable via a measurement of the change in one or more of the resistance and inductive reactance of the coil, as well as by other eddy current detection means. It should be understood that the described method of eddy current detection does not limit the invention, and other methods of inducing and detecting eddy currents known to those of ordinary skill in the art could be similarly used.

The induced eddy current in a region of the target 20 is related to a remaining thickness of the target 20 at the target region, and thus is related to an extent of erosion of the sputtering surface 22. The eddy current sensor 58 generates a signal in relation to the detected property of the eddy current, which can be analyzed to determine an extent of erosion of a target sputtering surface 20. In one version, the eddy current sensor 58 is provided over a region 23 of the target 20 that is susceptible to erosion, such as regions of the target that typically form sputtering grooves 24. In another version, a plurality of eddy current sensors 58 can be provided over different regions of the target 20 to detect an overall surface profile of the sputtering surface 22. The eddy current sensor 58 can be provided to continuously monitor the erosion extent of the sputtering surface 22, and can monitor both after as well as during processing of a substrate 104 in the sputtering chamber 106. An example of a suitable eddy current sensor 58 may be a GMR sensor (giant magnetoresistance sensor) available from Albany Instruments Inc., Charlotte N.C.

A sheet resistance sensor 59 can similarly be provided to determine an extent of erosion of the sputtering surface 22. The sheet resistance sensor 59 can be mounted on the back-side 60 of the target 20, such as on a backing plate 62. In general, the sheet resistance sensor 59 comprises a probe capable of passing a current through the target material at a specified region of the target 20. Characteristics of the current, such as the amplitude of the current or the associated voltage, are measured to determine the sheet resistance (Rs) in that region. Other methods of measuring a sheet resistance known to those of ordinary skill in the art can also be applied. An example of a suitable sheet resistance sensor 59 may be, for example, a four point probe sheet resistance measurement system available from Creative Design Engineering, Inc. in Cupertino, Calif.

The measured sheet resistance (Rs) is a function of the resistivity (ρ) of the target material divided by the thickness (t) of the target material at a region of the target. Because the sheet resistance of the target material changes with a change in thickness of the target 20 due to sputtering, the sheet resistance provides a measure of the remaining thickness target 20 and thus the extent of erosion of the target 20. In one version, the sheet resistance is measured at a plurality of regions across the target, to provide a measurement of the sputtering surface profile. The sheet resistance may also be measured over regions 23 of the target that are susceptible to erosion, such as over regions 23 that typically form sputtered grooves 24. Thus, the sheet resistance sensor 59 allows for continuous monitoring of a target material thickness, and thus an erosion extent of the target 20, in between, after and during the processing of substrates 104 in the chamber 106.

Accordingly, a target erosion monitoring system 42 comprising at least one of the embodiments described above can be provided to monitor erosion of the target 20 to obtain maximum usage of the target, substantially without over-sputtering or breaking-through the target 20. The target erosion monitoring system 42 and monitoring method can also comprise a combination of two or more of the described embodiments, such as for example the wireless receiver 40 and detection wafer 30 in combination with the sidewall sensors 44, or the eddy current sensor 58 in combination with the sheet resistance sensor 59. Monitoring the erosion of the target improves the target usage, reduces the waste associated with underused targets and reduces the contamination of substrates due to target break-through. Also, the target erosion monitoring system 42 may be capable of generating a surface profile of the sputtering surface 22 that can be used to refurbish the sputtering target by providing a volume of fresh sputtering material that is selected in relation to the measured surface profile. A method of refurbishing a target 20 according to a measured target profile is described, for example, in U.S. patent application Ser. No. 10/900,532 to Tsai et al, filed on Jul. 27, 2004, and entitled “Profile Detection and Refurbishment of Deposition Targets,” which is herein incorporated by reference in its entirety.

In one version, the one or more embodiments of the target erosion monitoring system 42 and method can be used in a sputtering chamber 106, an embodiment of which is shown in FIG. 5, to sputter deposit a layer such as one or more of tantalum, tantalum nitride, aluminum, aluminum nitride, titanium, titanium nitride, tungsten, tungsten nitride and copper, on the substrate 104. A substrate support 108 is provided for supporting the substrate 104 in the chamber 106 comprising chamber enclosure walls 112 that surround a process zone 109 in the chamber 106, including one or more sidewalls 115, ceiling 121 and bottom wall 123. The substrate 104 is introduced into the chamber 106 through a substrate loading inlet 111 in a sidewall 115 of the chamber 106 and placed on the support 108. The support 108 can be provided in the chamber by a substrate transport 110, and support lift bellows (not shown) and a lift finger assembly (also not shown) can be used to lift and lower the substrate 104 onto the support 108 during transport of the substrate 104 into and out of the chamber 106.

A sputtering gas supply 103 introduces sputtering gas into the chamber 106 to maintain the sputtering gas at a sub atmospheric pressure in the process zone 109. The sputtering gas is introduced into the chamber 106 through a gas inlet 133 that is connected via the gas inputs 125a,b to one or more gas sources 124, 127, respectively. One or more mass flow controllers 126 are used to control the flow rate of the individual gases, which may be premixed in a mixing manifold 131 prior to their introduction into the chamber 106 or which may be separately introduced into the chamber 106. The sputtering gas typically includes a non-reactive gas, such as argon or xenon, that when energized into a plasma, energetically impinges upon and bombards the target 20 to sputter material, such as copper, titanium, titanium nitride, aluminum, tantalum, or tantalum nitride, off from the target 20. The sputtering gas may also comprise a reactive gas, such as nitrogen. Also, other compositions of sputtering gas that include other reactive gases or other types of non-reactive gases, may be used as would be apparent to one of ordinary skill in the art.

An exhaust system 128 controls the pressure of the sputtering gas in the chamber 106 and exhausts excess gas and by-product gases from the chamber 106. The exhaust system 128 comprises an exhaust port 129 in the chamber 106 that is connected to an exhaust line 134 that leads to one or more exhaust pumps 139. A throttle valve 137 in the exhaust line 134 may be used to control the pressure of the sputtering gas in the chamber 106. Typically, the pressure of the sputtering gas in the chamber 106 is set to sub-atmospheric levels.

The sputtering chamber 106 comprises a sputtering target 20 that faces the substrate 104 to deposit material on the substrate 104. The sputtering chamber 106 may also have a shield 120 to protect a wall 112 of the chamber 106 from sputtered material, and which may also serve as grounding plane. The target 20 can be electrically isolated from the chamber 106 and is connected to a power source 122, such as a DC or RF power source. In one version, the power source 122, target 20, and shield 120 operate as a gas energizer 190 that is capable of energizing the sputtering gas to sputter material from the target 20. The power source 122 can electrically bias the target 20 relative to the shield 120 to energize the sputtering gas in the chamber 106 to form a plasma that sputters material from the target 20. The material sputtered from the target 20 by the plasma is deposited on the substrate 104 and may also react with gas components of the plasma to form a deposition layer on the substrate 104.

The chamber 106 can further comprise a magnetic field generator 135 that generates a magnetic field 105 near the target 20 to increase an ion density in a high-density plasma region 138 adjacent to the target 20 to improve the sputtering of the target material. In addition, an improved magnetic field generator 135 may be used to allow sustained self-sputtering of copper or sputtering of aluminum, titanium, or other metals; while minimizing the need for non-reactive gases for target bombardment purposes, as for example, described in U.S. Pat. No. 6,183,614 to Fu, entitled “Rotating Sputter Magnetron Assembly”; and U.S. Pat. No. 6,274,008 to Gopalraja et al., entitled “Integrated Process for Copper Via Filling,” both of which are incorporated herein by reference in their entirety. In one version, the magnetic field generator 135 generates a semi-toroidal magnetic field at the target 20. In another version, the magnetic field generator 135 comprises a motor 307 to rotate the magnetic field generator 135 about a rotation axis.

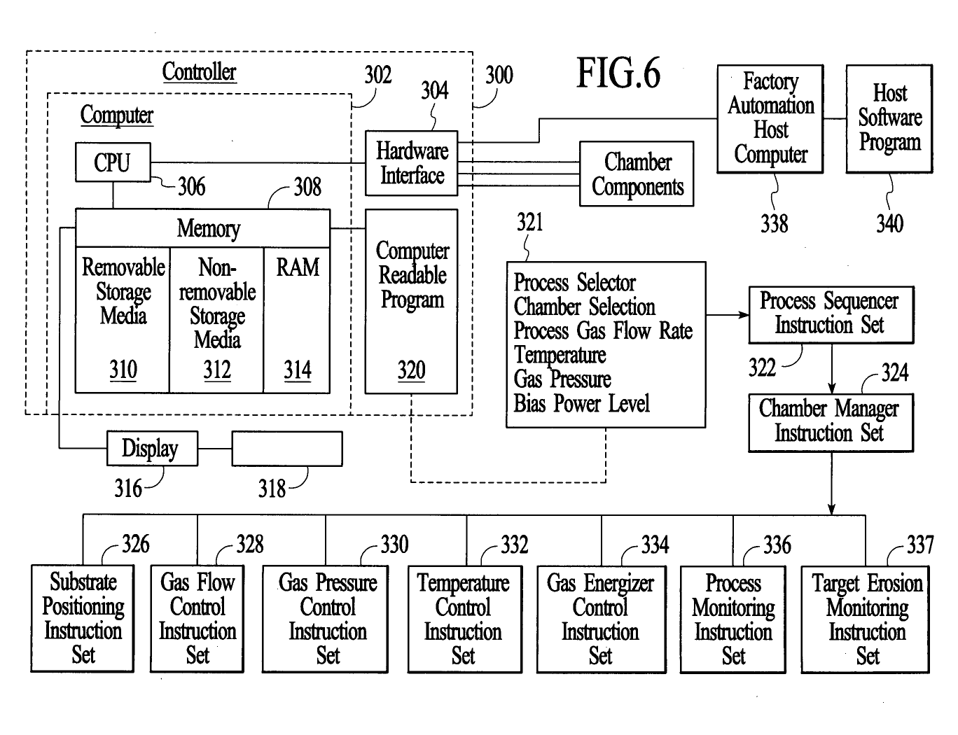

The substrate processing apparatus 102 comprising the sputter-deposition chamber 106 and target erosion monitoring system 42 may be operated by a controller 300 via a hardware interface 304. The controller 300 may comprise a computer 302 which may comprise a central processor unit (CPU) 306, such as for example a 68040 microprocessor, commercially available from Synergy Microsystems, California, or a Pentium Processor commercially available from Intel Corporation, Santa Clara, Calif., that is coupled to a memory 308 and peripheral computer components, as shown in FIG. 6. Preferably, the memory 308 may include a removable storage media 310, such as for example a CD or floppy drive, a non-removable storage media 312, such as for example a hard drive, and random access memory 314. The controller 300 may further comprise a plurality of interface cards including, for example, analog and digital input and output boards, interface boards, and motor controller boards. The interface between an operator and the controller 300 can be, for example, via a display 316 and a light pen 318. The light pen 318 detects light emitted by the monitor display 316 with a light sensor in the tip of the light pen 318. To select a particular screen or function, the operator touches a designated area of a screen on the monitor 316 and pushes the button on the light pen 318. Typically, the area touched changes color, or a new menu is displayed, confirming communication between the user and the controller 300.

In one version the controller 300 comprises a computer-readable program 320 may be stored in the memory 308, for example on the non-removable storage media 312 or on the removable storage media 310. The computer readable program 320 generally comprises process control software comprising program code to operate the chamber 106 and its components, process monitoring software to monitor the processes being performed in the chamber 106, safety systems software, and other control software, as for example, illustrated in FIG. 6. The computer-readable program 320 may be written in any conventional computer-readable programming language, such as for example, assembly language, C++, Pascal, or Fortran. Suitable program code is entered into a single file, or multiple files, using a conventional text editor and stored or embodied in computer-usable medium of the memory 308. If the entered code text is in a high level language, the code is compiled, and the resultant compiler code is then linked with an object code of precompiled library routines. To execute the linked, compiled object code, the user invokes the object code, causing the CPU 306 to read and execute the code to perform the tasks identified in the program.

FIG. 6 further provides an illustrative block diagram of a hierarchical control structure of a specific embodiment of a computer readable program 320 according to the present invention. Using a light pen interface, a user enters a process set and chamber number into the computer readable program 320 in response to menus or screens displayed on the CRT terminal. The computer readable program includes program selector program code 321 to select a chamber and control the substrate position, gas flow, gas pressure, temperature, RF power levels, and other parameters of a particular process, as well as code to monitor the chamber process. The process sets are predetermined groups of process parameters necessary to carry out specified processes. The process parameters are process conditions, including without limitations, gas composition, gas flow rates, temperature, pressure, gas energizer settings such as RF power levels.

The process sequencer instruction set 322 comprises program code to accept a chamber type and set of process parameters from the computer readable program 320 and to control its operation. The sequencer program 322 initiates execution of the process set by passing the particular process parameters to a chamber manager instruction set 324 that controls multiple processing tasks in the process chamber 106. Typically, the process chamber instruction set 324 includes a substrate positioning instruction set 326, a gas flow control instruction set 328, a temperature control instruction set 332, a gas energizer control instruction set 334, a process monitoring instruction set 336, and an exhaust control instruction set 330. The process chamber instruction set 324 can also comprise a target erosion monitoring instruction set 337.

Typically, the substrate positioning instruction set 326 comprises program code for controlling chamber components that are used to load a substrate 104 onto the support 108, such as a transport 110, and optionally, to lift the substrate 104 to a desired height in the chamber 106. The positioning instruction set 326 may also comprise program code to transport a detection wafer 30 in the chamber, and position the wafer 30 on the support 108. The gas flow control instruction set 328 comprises program code for controlling the flow rates of different constituents of the process gas. The gas flow control instruction set 328 operates the gas supply 103 and regulates the opening size of one or more mass flow controllers 126 to obtain the desired gas flow rate into the chamber 106. The temperature control instruction set 332 comprises program code for controlling temperatures in the chamber 106, such as the temperature of the substrate 104. The gas energizer control instruction set 334 comprises program code to operate the gas energizer 190 to set a gas energizing power level. The process monitoring instruction set 334 comprises code for monitoring the process in the chamber 106. The exhaust control instruction set 330 comprises program code for controlling the pressure in the chamber 106, for example by operating the exhaust system 128 and throttle valve 137 to maintain a pressure in the chamber 106.

The target erosion monitoring instruction set 337 comprises program code to operate the target erosion monitoring system 42 to monitor erosion of the target 20, as well as program code to analyze a signal generated by the erosion monitoring system to determine an extent of erosion of the target 20. For example, the target erosion monitoring instruction set 337 may comprise program code to determine when an erosion endpoint has occurred. The target monitoring instruction set 337 can comprise program code to generate a signal indicating that the endpoint has been reached, so the target can be refurbished and/or replaced. In another version, the target erosion monitoring instruction set 337 comprises program code to determine a surface profile of the eroded surface 22, which may comprise the depths of eroded regions 23 in the surface 22, or the remaining thickness of the target 20, at a plurality of different points across the surface 22. The determined surface profile can be used during a refurbishment process to supply fresh target material in the eroded regions 23 in a volume that is selected in relation to the calculated surface profile. The target erosion monitoring instruction set 337 may also comprise program code to initiate target monitoring after a predetermined number of substrates have been processed in the chamber 106.

For example, in the embodiment comprising the detection wafer 20 and wireless receiver 40, the target erosion monitoring instruction set 337 can comprise erosion determination program code to analyze the signal received by the wireless receiver 40 from the detection wafer 30. A distance to the sputtering surface 22 from the wafer 20 at one or more points can be calculated to determine an extent of erosion and pitting of the target surface 22. Once a distance has achieved a predetermined value that is indicative of maximum usage of the target 20, before break-through of the target 20 occurs, the erosion monitoring instruction set 337 may comprise program code to generate a signal indicating that the erosion endpoint has occurred, and may also generate a surface profile for use in refurbishing the target. The target erosion monitoring instruction set 337 may also comprise program code to set monitoring and detection parameters, for example by remotely controlling the detection wafer 30 to set parameters such as a detection wavelength, pulse length, and monitoring area. The detection wafer 30 can be controlled by sending a wireless signal to the detection wafer 30, for example by switching the roles of the wireless receiver 40 and transmitter 38. The target erosion monitoring instruction set 337 may also comprise detection wafer transport program code to control or initiate transport of the detection wafer 30 into the process chamber 106 to monitor the target sputtering surface 22 after a predetermined number of substrates having been processed.

In the embodiment comprising the sensors 44 mounted on the sidewall 115 of the chamber, the target erosion monitoring instruction set 337 may comprise program code to analyze a signal received from the sensors 44, and evaluate the erosion extent of the target 20, for example by determining distances from the sensors 44 to the surface 22, and thus the depths of eroded regions 23 in the surface 22 and a remaining thickness of the target material. The signal can also be analyzed to determine one or more of an erosion endpoint and sputtering surface profile. The target erosion monitoring instruction set 337 can also comprise program code to control the sensors 44 to set monitoring parameters, such as for example at least one of a wavelength of radiation detected, a rate and direction of scanning across the surface 33, and a scan duration. The shutters 50 may also be controlled by program code in the target erosion monitoring instruction set 337 to position the shutters 50 in a closed position that fits over the chamber recess 116 during substrate processing to protect the sensors 44, and position the shutters 50 in an open position during monitoring of the target 20 to allow the sensors 44 to direct radiation onto the sputtering surface 20 substantially unimpeded.

In the eddy current sensor embodiment as well as in the sheet resistance sensor embodiment, the target erosion monitoring instruction set 337 may comprise erosion monitoring program code to analyze the signals from the detectors, for example, to determine a remaining thickness of the target material at points on the target. Other properties of the target 20 may also be obtained by analyzing the signal. The target erosion monitoring instruction set 337 may also comprise program code to control detection parameters of the eddy current sensor 58 and/or sheet resistance sensor 59, such as an applied current, voltage and frequency, a measurement sensitivity, and a measurement position on the target 20.

The data signals received by and/or evaluated by the controller 300 may be sent to a factory automation host computer 338. The factory automation host computer 318 may comprise a host software program 340 that evaluates data from several systems, platforms or chambers 106, and for batches of substrates 104 or over an extended period of time, to identify statistical process control parameters of (i) the processes conducted on the substrates 104, (ii) a property that may vary in a statistical relationship across a single substrate 104, or (iii) a property that may vary in a statistical relationship across a batch of substrates 104. The host software program 340 may also use the data for ongoing in-situ process evaluations or for the control of other process parameters. A suitable host software program comprises a WORKSTREAM™ software program available from aforementioned Applied Materials. The factory automation host computer 338 may be further adapted to provide instruction signals to (i) remove particular substrates 104 from the processing sequence, for example, if a substrate property is inadequate or does not fall within a statistically determined range of values, or if a process parameter deviates from an acceptable range; (ii) end processing in a particular chamber 106, or (iii) adjust process conditions upon a determination of an unsuitable property of the substrate 104 or process parameter. The factory automation host computer 338 may also provide the instruction signal at the beginning or end of processing of the substrate 104 in response to evaluation of the data by the host software program 340.

The present invention has been described with reference to certain preferred versions thereof; however, other versions are possible. For example, the target erosion monitoring can be used in other types of sputtering applications, as would be apparent to one of ordinary skill. Other configurations of the target monitoring systems 42 can also be used. Further, alternative steps equivalent to those described for the monitoring methods can also be used in accordance with the parameters of the described implementation, as would be apparent to one of ordinary skill. Therefore, the spirit and scope of the appended claims should not be limited to the description of the preferred versions contained herein.

What is claimed is:

1. A target sputtering apparatus capable of monitoring target erosion, the apparatus comprising:
(a) a sputtering chamber comprising
(i) a sputtering target having a sputtering surface;
(ii) a substrate support facing the sputtering target;
(iii) a transport;
(iv) a sputtering gas supply;
(v) a gas energizer; and
(vi) a gas exhaust,
whereby sputtering gas can be maintained at a pressure in the chamber and energized to sputter material from the sputtering surface of the sputtering target;
(b) a wireless receiver to receive a wireless signal; and
(c) a controller to control the support, transport, sputtering target, gas supply, gas energizer, gas exhaust and receiver, the controller comprising:
(i) process control program code to sputter-deposit material on a substrate; and
(ii) target erosion monitoring code to monitor erosion of the sputtering surface of the sputtering target, the target erosion monitoring code comprising:
(1) detection wafer transport program code to transport a detection wafer onto the support in the chamber, the detection wafer being capable of generating a wireless signal in relation to an extent of erosion of the sputtered surface; and
(2) erosion determination code to analyze the wireless signal received by the wireless receiver and originating from the detection wafer to determine an extent of erosion of the sputtering surface of the sputtering target.

2. An apparatus according to claim 1 wherein the receiver is outside the chamber enclosure walls.

3. An apparatus according to claim 1 wherein the controller analyzes a wireless signal generated by the detection of radiation reflected from the sputtered surface.

4. An apparatus according to claim 1 wherein the controller sends a signal to the detection wafer to control the erosion detection parameters.

5. An apparatus according to claim 1 wherein the controller analyzes the wireless signal to determine when an erosion endpoint has occurred, the erosion endpoint being the point at which the target has been sputtered to a predetermined maximum state.

6. An apparatus according to claim 1 wherein the controller analyzes the wireless signal to determine an erosion profile of the sputtered surface.

7. A method of monitoring a sputtering target in a process chamber, the method comprising:
(a) sputtering the target in the process chamber to form a sputtered surface on the target;
(b) providing a detection wafer on a support facing the target, the detection wafer comprising a plurality of sensors capable to detect an extent of erosion of the sputtered surface and generate a signal in relation to the extent of erosion; and
(c) wirelessly transmitting the signal to a receiver; and
(d) analyzing the signal to determine the extent of erosion of the sputtered surface.

8. A method according to claim 7 wherein (b) comprises providing a detection wafer comprising a plurality of sensors to direct radiation onto the sputtered surface and detect radiation reflected from the sputtered surface.

9. A method according to claim 8 wherein (b) comprises providing a detection wafer comprising sensors to detect a distance to the sputtered surface.

10. A method according to claim 7 wherein (c) comprises wirelessly transmitting the signal through chamber enclosure walls to a receiver that is outside the chamber enclosure walls.

11. A method of measuring a surface profile of an asymmetrically sputtered region of a sputtering target in a process chamber, the method comprising:
(a) providing a detection wafer on a support facing the target, the detection wafer comprising a plurality of sensors capable of measuring the surface profile of substantially the entire asymmetrically sputtered region of the sputtering target, in-situ in the chamber, and substantially without movement of the detection wafer during the measurement;
(b) generating a signal in relation to the measured surface profile; and
(c) analyzing the signal to determine the surface profile of the asymmetrically sputtered region of the sputtering target.

12. A method according to claim 11 wherein (a) comprises measuring a surface profile of an asymmetrically sputtered region comprising an annular track, and wherein (c) comprises determining the annular track surface profile.

13. A method according to claim 11 wherein (a) comprises measuring a distance from the detection wafer to the asymmetrically sputtered region of the target.

14. A method according to claim 11 further comprising wirelessly transmitting the signal through chamber enclosure walls to a receiver that is outside the enclosure walls.

15. A wafer to monitor a sputtering target in a process chamber, the wafer comprising:
(a) a disc to be held by a support in a process chamber;
(b) a plurality of sensors on a top surface of the disc, the sensors comprising a radiation source to direct radiation onto a surface of the sputtering target, and a detector to detect radiation reflected by the surface and generate a signal in relation to the detected radiation; and
(c) a wireless transmitter to receive the signal from the detector, and wirelessly transmit the signal to a receiver that is outside of the process chamber.

16. A wafer capable of measuring a surface profile of an asymmetrically sputtered region of a sputtering surface on a sputtering target in a process chamber, the wafer comprising:
(a) a disc to be held by a support in the process chamber, the disc having a top surface; and
(b) a plurality of sensors spaced apart and arranged on the top surface to measure, in-situ in the chamber, a surface profile of substantially the entire asymmetrically sputtered region of the sputtering target, the sensors comprising a radiation source to direct radiation onto the sputtering surface of the sputtering target and a detector to detect radiation reflected by the sputtering surface and generate a signal in relation to the detected radiation.

17. A wafer according to claim 16 wherein the sensors are capable of measuring the surface profile of the asymmetrically sputtered region substantially without moving the disc during measurement of the surface profile.

18. A wafer according to claim 16 wherein the asymmetrically sputtered region comprises an annular track, and wherein the sensors are spaced apart and arranged in an annular shape on the disc.

19. A wafer according to claim 18 wherein the annular track is located about a periphery of the target, and wherein the sensors are spaced apart and arranged in an annular shape about a peripheral region of the disc.

20. A wafer according to claim 18 wherein the annular track is located about midway on the radius of the target, and wherein the sensors are spaced apart and arranged in an annular shape located between a center region and a peripheral region of the disc.

21. A wafer according to claim 16 further comprising a wireless transmitter to receive the signal from the detector, and wirelessly transmit the signal to a receiver that is outside of the process chamber.

22. A sputtering apparatus for sputter-depositing material on a substrate, and monitoring target erosion, the apparatus comprising:
(a) a sputtering chamber comprising:
(i) a sputtering target having a sputtering surface;
(ii) a substrate support facing the sputtering target;
(iii) a transport;
(iv) a sputtering gas supply;
(v) a gas energizer; and
(viii) a gas exhaust,
whereby sputtering gas can be maintained at a pressure in the chamber and energized to sputter material from the sputtering surface of the sputtering target;
(b) a sensor mounted on a sidewall of the chamber, wherein the sensor directs radiation at the sputtering surface of the target, detects radiation reflected from the sputtering surface, and generates a signal in relation to the detected radiation; and
(c) a controller to control the sensor, support, transport, sputtering target, gas supply, gas energizer and gas exhaust, the controller comprising:
(i) process control program code to sputter-deposit material on a substrate; and
(ii) target erosion monitoring code to analyze the signal generated by the sensor to determine an extent of erosion of the sputtering surface of the sputtering target.

23. An apparatus according to claim 22 wherein the sensor detects a distance to the sputtered surface, and generates a signal in relation to the detected distance.

24. An apparatus according to claim 22 wherein the controller analyzes the sensor signal to determine when an erosion endpoint has occurred, the erosion endpoint being the point at which the target has been sputtered to a predetermined maximum state.

25. An apparatus according to claim 22 wherein the controller analyzes the signal to determine an erosion profile of the sputtered surface.

26. An apparatus according to claim 22 wherein the chamber sidewall comprises a recess sized to fit the sensor, and wherein the chamber further comprises a shutter that fits over the recess to inhibit erosion of the sensor while sputter-depositing material on a substrate.

27. An apparatus according to claim 22 wherein the sensor scans a beam of radiation across the sputtered surface of the target.

28. A method of monitoring a sputtering target in a process chamber, the method comprising:
(a) sputtering the target in the process chamber to form a sputtered surface on the target;
(b) directing radiation towards the sputtered surface from a sidewall of the process chamber; and
(c) receiving radiation reflected towards the sidewall from the sputtered target, and generating a signal in relation to the received radiation to determine an extent of erosion of the sputtered surface region.

29. A method according to claim 28 comprising analyzing the signal to determine when an erosion endpoint has occurred, the erosion endpoint being the point at which the target has been sputtered to a predetermined maximum extent.

30. A method according to claim 28 comprising analyzing the signal to determine an erosion profile of the sputtered surface.

31. A sputtering apparatus for sputter-depositing material on a substrate, and monitoring target erosion, the apparatus comprising:
(a) a sputtering chamber comprising:
(i) a sputtering target comprising a front side with a sputtering surface, and a back-side that is opposite the sputtering surface;
(ii) a substrate support facing the sputtering target;
(iii) a transport;
(iv) a sputtering gas supply;
(v) a gas energizer; and
(vi) a gas exhaust,
whereby sputtering gas can be maintained at a pressure in the chamber and energized to sputter material from the sputtering surface of the sputtering target;
(b) an eddy current sensor mounted on the back side of the sputtering target, wherein the eddy current sensor detects an eddy current in the sputtering target and generates a signal in relation to the detected eddy current; and
(c) a controller to control at least one of the eddy current sensor, substrate support, substrate transport, sputtering target, gas supply, gas energizer and gas exhaust, the controller comprising:
(i) process control program code to sputter-deposit material on a substrate; and
(ii) target erosion monitoring code to analyze the signal generated by the eddy current sensor to determine an extent of erosion of the sputtered surface.

32. An apparatus according to claim 31 wherein the eddy current sensor detects a remaining thickness of the sputtering target.

33. An apparatus according to claim 31 wherein the controller analyzes the eddy current sensor signal to determine when an erosion endpoint has occurred, the erosion endpoint being the point at which the target has been sputtered to a predetermined maximum.

34. An apparatus according to claim 31 wherein the controller analyzes the eddy current signal to determine an erosion profile of the sputtered surface.

35. A method of monitoring a sputtering target in a process chamber, the method comprising:
(a) mounting an eddy current sensor on a back side of the sputtering target;
(b) sputtering a front side of the sputtering target in the process chamber to form a sputtered surface on the target; and
(c) detecting an eddy current in the sputtering target, and generating a signal in relation to the eddy current to determine an extent of erosion of the target.

36. A method according to claim 35 comprising analyzing the signal to determine when an erosion endpoint has occurred, the erosion endpoint being the point at which the target has been sputtered to a predetermined maximum extent.

37. A method according to claim 35 comprising analyzing the signal to determine an erosion profile of the sputtered surface.

38. A sputtering apparatus for sputter-depositing material on a substrate, and monitoring target erosion, the apparatus comprising:
(a) a sputtering chamber comprising:
(i) a sputtering target comprising a front side with a sputtering surface, and a back-side that is opposite the sputtering surface;
(ii) a substrate support facing the sputtering target;
(iii) a transport;
(iv) a sputtering gas supply;
(v) a gas energizer; and
(vi) a gas exhaust,
whereby sputtering gas can be maintained at a pressure in the chamber and energized to sputter material from the sputtering surface of the sputtering target;
(b) a sheet resistance sensor mounted on the back side of the sputtering target, wherein the sheet resistance sensor detects a sheet resistance of the sputtering target and generates a signal in relation to the detected sheet resistance; and
(c) a controller to control at least one of the sheet resistance sensor, substrate support, substrate transport, sputtering target, gas supply, gas energizer and gas exhaust, the controller comprising:
(i) process control program code to sputter-deposit material on a substrate; and
(ii) target erosion monitoring code to analyze the signal generated by the sheet resistance sensor to determine an extent of erosion of the sputtered surface.

39. An apparatus according to claim 38 wherein the sheet resistance sensor detects a remaining thickness of the sputtering target.

40. An apparatus according to claim 38 wherein the controller analyzes the sheet resistance sensor signal to determine when an erosion endpoint has occurred, the erosion endpoint being the point at which the target has been sputtered to a predetermined maximum.

41. An apparatus according to claim 38 wherein the controller analyzes the sheet resistance signal to determine an erosion profile of the sputtered surface.

42. A method of monitoring a sputtering target in a process chamber, the method comprising:
(a) mounting a sheet resistance sensor on a back side of the sputtering target;
(b) sputtering a front side of the sputtering target in the process chamber to form a sputtered surface on the target; and
(c) detecting a sheet resistance in the sputtering target, and generating a signal in relation to the detected sheet resistance to determine an extent of erosion of the target.

43. A method according to claim 42 comprising analyzing the signal to determine when an erosion endpoint has occurred, the erosion endpoint being the point at which the target has been sputtered to a predetermined maximum extent.

44. A method according to claim 42 comprising analyzing the signal to determine an erosion profile of the sputtered surface.
